(19) United States
(12) Patent Application Publication
(10) Pub. No.: US 2003/0114016 A1
(43) Pub. Date: Jun. 19, 2003

(54) Wafer carrier for semiconductor process tool

(76) Inventor: Michael A. Tischler, Phoenix, AZ (US)

Correspondence Address: ATMI, INC., 7 COMMERCE DRIVE, DANBURY, CT, 06810, US

(21) Appl. No.: 10/022,316

(22) Filed: Dec. 18, 2001

(51) Int. Cl. H01L 21/31

(52) U.S. Cl. 438/758

(57) ABSTRACT

A wafer carrier enabling a wafer of different size and/or shape to be processed in a process tool configured for processing a wafer of a predetermined size and/or shape, wherein the wafer carrier has such predetermined size and/or shape and includes at least one recess therein having the different size and/or shape. The wafer carrier enables the use in a process tool (e.g., a semiconductor epitaxial thin film deposition reactor such as a single wafer reactor) of differently sized wafers than those for which the process tool is designed.

### BACKGROUND OF THE INVENTION

1. Field of the Invention

The present invention relates to a wafer carrier enabling a wafer of different size and/or shape to be processed in a process tool, e.g., a single wafer epitaxial reactor, that is configured for processing a wafer of a predetermined size and/or shape.

2. Description of the Related Art

Single wafer epitaxial reactors are constructed and operated to deposit epitaxial thin film material, or “epi,” on a single substrate at a time.

If epi is desired to be deposited on a wafer of a different diameter, the epitaxial reactor system must be disassembled and reconfigured for a wafer of a different diameter. Such reconfiguration not only involves installation of different components to accommodate a new diameter wafer, but the time involved in such reconfiguration, in cleaning the reactor and ensuring its leak-tightness and operability after being open to the ambient atmosphere, is time-consuming and costly.

It would therefore be a substantial advance in the art to provide a means and method for enabling a single wafer reactor to process multiple diameter wafers in an easier fashion and with less cost.

### SUMMARY OF THE INVENTION

The present invention relates generally to a wafer carrier for use with a process tool, e.g., an epitaxial thin film deposition reactor such as a single wafer epitaxial reactor.

In one aspect, the present invention relates to a wafer carrier enabling a wafer of different size and/or shape to be processed in a process tool configured for processing a wafer of a predetermined size and/or shape, wherein the wafer carrier has such predetermined size and/or shape and includes at least one recess therein having the different size and/or shape.

In another aspect, the invention relates to a wafer carrier/wafer article comprising a wafer carrier of such type.

Yet another aspect of the invention relates to a process tool system, comprising:

(i) a process tool including a susceptor or wafer holder having at least one recess therein of a first size and/or shape;

(ii) at least one wafer carrier of a size and shape to closely fit in a recess of said susceptor or wafer holder, said wafer carrier having a recess therein of a second size and/or shape differing from said first size and/or shape; and

(iii) at least one wafer of a size and shape to closely fit in the recess of said wafer carrier.

A further aspect of the invention relates to an epitaxial reactor system, comprising:

(i) an epitaxial reactor comprising a susceptor having at least one recess therein of a first size and/or shape;

(ii) at least one wafer carrier of a size and shape to closely fit in a recess of said susceptor, said wafer carrier having a recess therein of a second size and/or shape differing from said first size and/or shape; and

(iii) at least one wafer of a size and shape to closely fit in the recess of said wafer carrier.

Yet another aspect of the invention relates to a method of processing a wafer in an epitaxial reactor including a susceptor having a recess therein of different size and/or shape than the wafer. Such method comprises:

providing a wafer carrier having (i) a size and shape to closely fit in the recess of the susceptor, and (ii) one or more recesses therein with a size and shape accommodating close-fit positioning of the wafer(s) therein;

positioning the wafer(s) in the wafer carrier recess to form a wafer carrier/wafer article;

positioning the wafer carrier/wafer article in the susceptor recess in the epitaxial reactor; and

processing the wafer in the epitaxial reactor to carry out at least one semiconductor manufacturing operation thereon.

Other aspects, features and embodiments of the invention will be more fully apparent from the ensuing disclosure and appended claims.

### BRIEF DESCRIPTION OF THE DRAWINGS

FIG. 1 is a sectional elevation view of a single wafer reactor in which a wafer carrier according to one embodiment of the invention is reposed in a recess of a susceptor mounted in the reactor, immediately after the wafer carrier is released by a robotic wafer transfer device.

FIG. 2 is a perspective view of the wafer carrier of FIG. 1.

FIG. 3 is a perspective exploded view of a susceptor of a multi-wafer reactor, one of the multiple wafer carriers reposed in one of the recesses of the susceptor, and a wafer reposed in the wafer carrier.

FIG. 4 is a sectional elevation view of a pedestaled wafer carrier according to one embodiment of the invention, reposed in a recess of a susceptor mounted in a reactor.

FIG. 5 is a sectional elevation view of a multi-recess wafer carrier according to another embodiment of the invention, reposed in a recess of a susceptor mounted in a reactor.

FIG. 6 is a graph of boron concentration and germanium concentration, as a function of depth in the wafer, in Angstroms, for a 100 mm diameter wafer grown using a wafer carrier in accordance with the present invention, and a corresponding 150 mm diameter wafer grown directly in the reactor (without the use of said wafer carrier).

### DETAILED DESCRIPTION OF THE INVENTION, AND PREFERRED EMBODIMENTS THEREOF

The present invention relates to a wafer carrier that is usefully employed with a process tool, e.g., an epitaxial thin film deposition reactor such as a single wafer epitaxial reactor employed in the manufacture of semiconductor devices and materials.

In a specific application, the wafer carrier of the present invention enables the use in epitaxial thin film deposition reactors, e.g., single wafer reactors, of differently sized wafers than those for which the reactor is constructed and arranged.

The wafer carrier of the invention comprises a main carrier body having a recess holding a wafer. The wafer in preferred practice is dimensionally close-fit to the recess, so that the wafer may be readily inserted into and readily withdrawn from the recess, e.g., with a gap of only 0.25-2 mm between the side edge of the wafer and the edge of the recess in which the wafer is reposed.

In one embodiment, the wafer carrier of the invention comprises a generally planar body, preferably of circular shape. The wafer carrier has a diameter and thickness of any suitable dimensions that permit it to be reposed in the recess of a susceptor in the epitaxial reactor, e.g., a single wafer reactor, with which the wafer carrier is used. The body of the wafer carrier in turn has a recess therein. This wafer body recess is shaped to hold therein, preferably in a dimensionally close-fit manner, a wafer of smaller size than a wafer sized to be directly reposed, e.g., in dimensionally close-fit manner, in the susceptor recess of the aforementioned susceptor in the epitaxial reactor.

In an alternative embodiment, the wafer carrier may have a larger diameter than the recess in the corresponding susceptor, with a short “pedestal” that fits into the recess of the susceptor. In such embodiment, a wafer diameter larger than that of the recess in the corresponding susceptor may be processed.

Although described herein primarily with reference to susceptors, wafer carriers and wafers of circular/cylindrical character, having generally disk-like form, it will be recognized that the invention is not thus limited, but extends to and includes other geometric forms, shapes and conformations of each of the susceptor, wafer carrier and wafer elements that are geometrically compatible with one another. Examples of such alternative geometries include square and rectangular geometries, oval and elongate geometries, etc. The associated geometries may be regular or irregular in character.

In one embodiment, the wafer is close-fit in the recess of a wafer carrier that is close-fit in the recess of a susceptor of the epitaxial reactor, so that the wafer carrier has the general size and dimensions of a wafer that normally is used with the susceptor of the epitaxial reactor.

The wafer carrier may be formed of any suitable material of construction, e.g., silicon carbide, silicon, quartz, graphite, boron nitride, aluminum oxide, aluminum nitride, silicon carbide on graphite, titanium carbide on graphite, glassy carbon, sapphire, indium phosphide, gallium antimonide, gallium arsenide and III-V nitrides.

The wafer carrier may be formed of a same material of construction as the wafer itself, e.g., silicon carbide, silicon, quartz, graphite, boron nitride, aluminum oxide, aluminum nitride, titanium carbide, glassy carbon, sapphire, indium phosphide, gallium antimonide, gallium arsenide and III-V nitrides.

The epitaxial reactor may be of any suitable type. Preferably the epitaxial reactor is a single wafer reactor, although reactors constructed and arranged for simultaneously processing a multiplicity of substrates are also usefully employed in the broad practice of the present invention. As used herein, the term epitaxial reactor means a reactor that is constructed and arranged to carry out the deposition of epitaxial film materials on a substrate.

The invention in another aspect relates to the combination of an epitaxial reactor, e.g., having an automatic wafer handling system associated therewith, with one or more wafer carriers adapted to be reposed in a susceptor of the epitaxial reactor and one or more wafers adapted to be reposed in recess(es) of the wafer carrier(s). Preferably the engagement of the wafer with the recess of the wafer carrier is close-fit in character.

The recess in the wafer carrier preferably has a flat floor so that a correspondingly flat wafer can be reposed in the recess with a main bottom face of the wafer in contact over its facial area with the floor of the recess. This ensures thermal contact over the facial area with the wafer carrier. The wafer carrier correspondingly preferably has a flat main bottom face that is reposable in direct contact with the recess in the susceptor over the bottom facial area of the wafer carrier. Other configurations may be desirable, for example a concave recess profile, such that the wafer and/or wafer carrier is/are supported only by its/their edges.

While the wafer carrier is shown hereinafter in one aspect with reference to a wafer carrier having multiple recesses therein, each of the same size and geometric character, the invention is not limited in such respect, and a wafer carrier having differently sized and/or shaped recesses therein is usefully employed for wafers of corresponding respective sizes and/or shapes.

The wafer carrier of the invention provides a means of adapting multiple wafer diameters for processing in a specific reactor without the need to disassemble, reconfigure and reconstruct the reactor.

In one embodiment, the wafer carrier has the same general physical dimensions as the wafer (here termed “standard wafer”) that is normally used in the epitaxial reactor (as determined by the size of the recess or receiving surface of the susceptor, e.g., a 150 mm diameter), except that the wafer carrier can be somewhat thicker than the standard wafer. In such embodiment, the wafer carrier is machined or otherwise formed with a recess in the top face thereof to hold a wafer of smaller diameter, e.g., a 100 mm diameter wafer. The use of this wafer carrier enables a cassette of smaller wafers to be processed in an epitaxial reactor configured for a larger diameter wafer, with essentially no change in reactor configuration.

The wafer carrier is suitably formed of any appropriate material of construction. Preferably the material of construction satisfies the following materials selection criteria:

(i) it does not introduce impurities to the wafer or material deposited thereon or therein (e.g., out-diffusion of impurities from the wafer carrier during thermal cycling, by mechanical contact or by subsurface ion implantation in prior or subsequent processing);

(ii) it does not introduce particles to the wafer or material deposited thereon;

(iii) it provides a sufficiently close thermal match to the wafer so as not to “pinch” the wafer, and so as not to create too much space (gap) between the wafer side edge and the facing side wall of the recess in the wafer carrier so that the wafer is “loose” in the recess of the wafer carrier;

(iv) it does not compromise the epitaxial process (or other prior or subsequent wafer processing steps);

(v) it allows acceptable transfer of heat to the wafer held in the wafer carrier recess during processing in the reactor; and

(vi) it permits the wafer carrier to hold the substrate in place all through the process, including, if desired, automatic transfer of the wafer and carrier in and out of the process chamber, using standard robotic mechanisms.

The wafer carrier can be made of the same material of construction as the wafer itself, or alternatively the wafer carrier can be made of a different material of construction. Examples of preferred wafer carrier materials of construction include silicon carbide, silicon, quartz, sapphire, gallium arsenide and III-V nitrides such as gallium nitride, gallium indium nitride, etc.

The wafer carrier can be made of a different material than the wafer, in which case the wafer carrier material of construction is etch-resistant to etch media and conditions that are employed to etch the wafer. This permits the wafer carrier to be readily cleaned by such media and conditions, e.g., subsequent to its use.

While the invention is described primarily herein as involving the use of a wafer carrier for wafer(s) processed in an epitaxial reactor, such usage is not the only application of the invention, and the invention can be advantageously employed in other applications, e.g., involving other wafer handling equipment and/or or other tools.

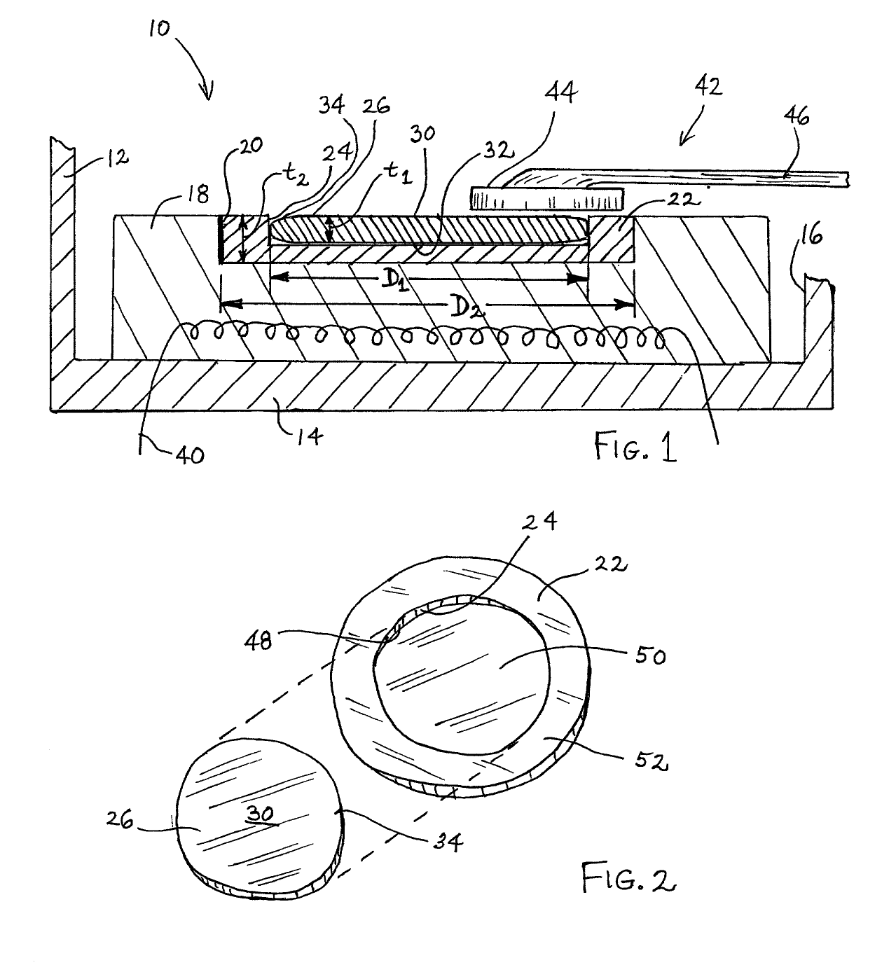

Referring now to the drawings, FIG. 1 is a sectional elevation view of a single wafer reactor 10 in which a wafer carrier 22 according to one embodiment of the invention is reposed in a recess 20 of a susceptor 18 mounted in the reactor, immediately after the wafer carrier is released by a robotic wafer transfer device 42.

The reactor 10 includes a reactor housing comprising side walls 12 and 16 joined at their respective lower ends to a floor member 14 to form an enclosed interior volume of the reactor to which vapor phase material is introduced to effect deposition of an epitaxial film on a substrate wafer 26.

The reactor 10 includes a susceptor 18 which in the specific embodiment shown has a heating element 40 embedded therein for heating of the susceptor to appropriate elevated temperature when the reactor is operated for epitaxial film deposition operation. The susceptor may be otherwise heated, e.g., by radiative heating, by RF induction heating, by flow of a heat transfer fluid therethrough in interior passages (not shown in FIG. 1) or otherwise by conductive heating or other heating modality, using appropriate means and operative methods therefor.

The susceptor recess 20 as shown is bounded by a floor and side surfaces of the susceptor 18. Reposed in close-fit relationship to this recess is the wafer carrier 22. The wafer carrier 22 correspondingly has a recess 24 therein. The wafer carrier recess likewise is bounded by a floor and side surfaces of the wafer carrier. Reposed in close-fit relationship to the wafer carrier recess 24 is a wafer 26.

The wafer 26 is of planar disk form, having a main top surface 30 and a main bottom surface 32. The wafer has a peripheral edge region that may be shaped with beveled or otherwise thinned edges to facilitate insertion of the wafer into and removal of the wafer from the slots in an associated wafer carrier cassette (not shown in FIG. 1).

The wafer carrier in FIG. 1 is shown immediately after it has been inserted in the susceptor recess 20 and then been released by the robotic wafer transfer device 42. The wafer and wafer carrier are loaded together by the transfer device. Such concurrent loading of the wafer and wafer carrier avoids having to separately load them and thereby opening the chamber to the ambient air, and increasing the effort involved. The robotic wafer transfer device 42 can be of a conventional wand type, with a wand head 44 joined to an extension arm 46, wherein the wand head is arranged to selectively exert suction to effect pickup, retention and transfer of the wafer and wafer carrier, and to selectively terminate suction to release the substrate article.

Alternatively, the robotic wafer transfer device 42 can be of a mechanical gripper type, or a shovel type (in which the wafer carrier is supported on the transfer tool from underneath, or of any other suitable type appropriate to the process chamber and/or manufacturing process.

The wafer in FIG. 1 is of disk-like cylindrical shape, having a diameter D₁ and a thickness t₁. The wafer is reposed in a close-fit manner in the recess of the wafer carrier 22, with the wafer carrier having a corresponding disk-like cylindrical shape in the embodiment shown, with a diameter D₂ and a thickness t₂.

By way of illustration, the diameter D₂ can for example be 150 mm and the thickness t₂ 0.675 mm, and the diameter D₁ can be 100 mm or 120 mm, with a thickness t₁ of 0.625 mm.

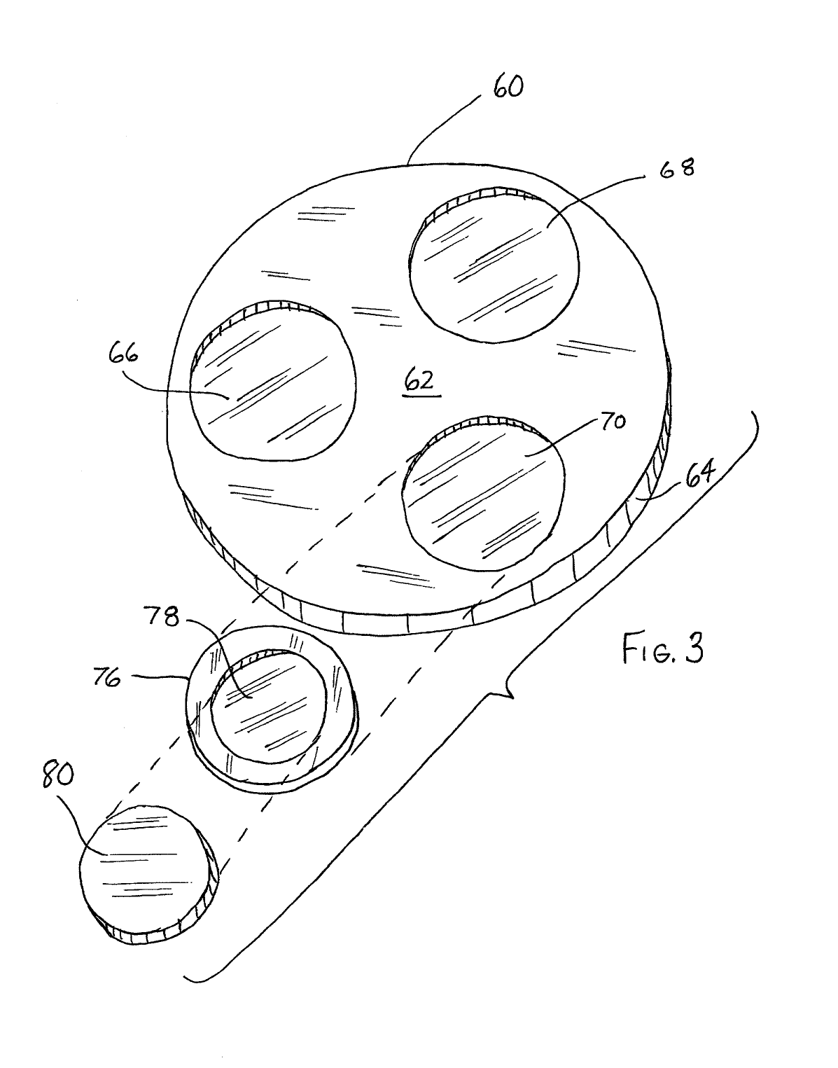

FIG. 2 is a perspective view of the wafer carrier of FIG. 1, wherein the same reference numbers are used to identify the same elements in the respective figures. As shown, the wafer carrier 22 has a recess 24 bounded by the recess side wall 48 and the recess floor 50, forming a circular cylindrical cavity in the wafer carrier and thereby defining an annular portion 52 of increased thickness t₂ (see FIG. 1) circumscribing the recess 24. The recess 24 has a depth of t_{1,} with reference to the thicknesses shown in FIG. 1.

The wafer should be held snugly and frictionally in the recess of the wafer carrier, but without binding, and the wafer handling equipment, e.g., the robotic wafer transfer device 42 shown in FIG. 1, is adapted to pick up, transfer and release the wafer and the wafer carrier (having the wafer reposed in the recess thereof), as a unitary wafer/wafer carrier assembly.

The thickness of the wafer carrier t₂ may be the same as that of a wafer with equivalent diameter. This maintains compatibility with automatic wafer handling equipment that utilizes cassettes with slots of standard dimensions for holding wafers.

In an alternative embodiment, the thickness of the wafer carrier t₂ may desirably be greater than the thickness of a wafer with equivalent diameter. In this case, the thickness of the outer edge of the wafer carrier may be reduced to conform to that of a wafer with equivalent diameter, to ensure compatibility with automatic wafer handling cassettes, as hereafter shown in FIG. 5.

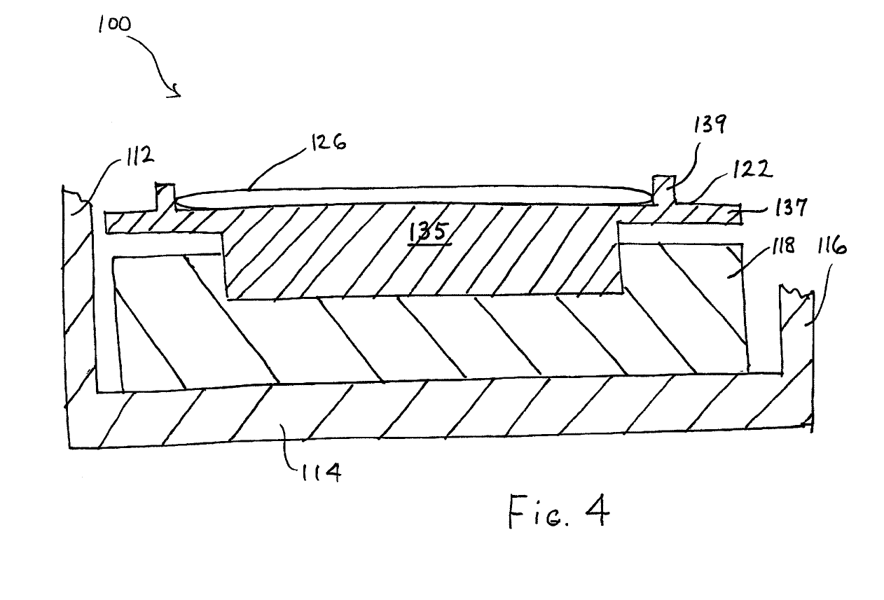

FIG. 3 is a perspective exploded view of a susceptor 60 of a multi-wafer reactor, one of the multiple wafer carriers 76 reposed in one of the recesses of the susceptor, and a wafer 80 reposed in the recess of the wafer carrier.

As illustrated, the susceptor 60 is of disk-like cylindrical form, having a vertical side edge 64 and a flat top surface 62 (with the bottom surface being correspondingly flat in character). The susceptor has in its top surface 62 three recesses 66, 68 and 70. It will be appreciated that the susceptor does not have to have flat top and bottom surfaces, and that other forms and topographies may be advantageously employed in the broad practice of the invention.

Each of these recesses is sized to accommodate therein a wafer carrier 76, with only a single wafer carrier associated with recess 70 being shown in FIG. 3 for ease of description, it being understood that a corresponding respective wafer carrier is reposable in each of the other susceptor recesses 66 and 68.

The wafer carrier 76 in turn has a central recess 78 therein, the recess being of circular cylindrical shape and coaxial with the overall circular cylindrical shape of the wafer carrier, so that the annular collar portion of the wafer carrier circumscribes the recess 78.

A wafer 80 is shown in exploded relationship to the recess 78 in the wafer carrier 76, being reposable therein in close-fit relationship, so that the wafer is in recess 78, and the wafer carrier 76 is in recess 70, when the overall susceptor/wafer carrier/wafer assembly is fully structurally engaged.

It will be appreciated that the respective recesses 66, 68 and 70 in FIG. 3, although shown as being of a same diameter and depth, could alternatively be provided with different respective diameters and depths in the separate ones of the recesses, in relationship to one another, to accommodate correspondingly different sized and shaped wafers. It will also be appreciated that each wafer carrier 76 could contain a multiplicity of recesses to accommodate a multiplicity of wafers.

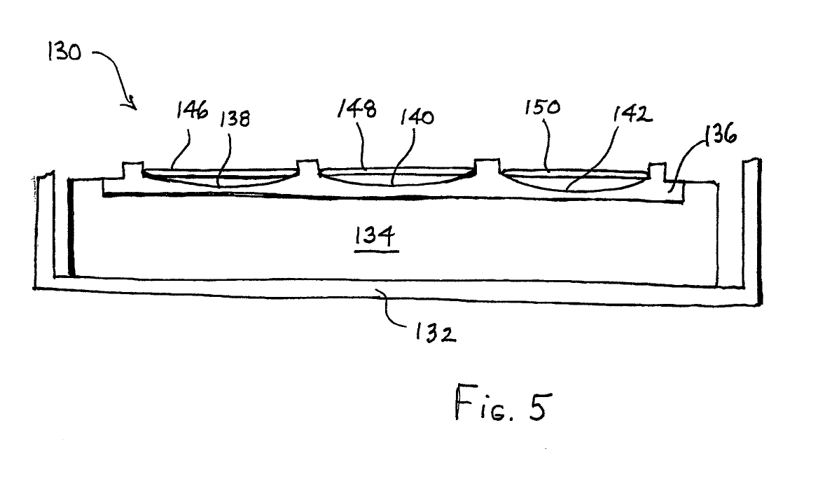

FIG. 4 is a sectional elevation view of a pedestaled wafer carrier 122 according to one embodiment of the invention, reposed in a recess of a susceptor 118 mounted in a single wafer reactor 100.

The reactor 100 includes a reactor housing comprising floor 114 and side walls 112 and 116 joined thereto, thereby forming an interior volume of the reactor to which vapor phase material is introduced for contacting with the wafer 126.

The susceptor 118 is suitably heated to an appropriate temperature for the vapor contacting operation, and may contain embedded heat transfer means or passages in the susceptor accommodating flow of a heat transfer fluid therethrough, or otherwise be equipped for operating at the temperature of the vapor contacting step.

The susceptor contains a recess in which the wafer carrier 122 is disposed. As illustrated, the wafer carrier 122 has a central columnar body 135. At the upper end of the columnar body flange 137 extends radially outwardly and is circumferentially continuous about the periphery of the columnar body, and an upstanding retention lip 139 is positioned on an upper surface of the flange 137. The retention lip is of cylindrical form, and thereby forms with the top surface of the wafer carrier a recess that is radially interior to the lip. In this recess is disposed the wafer 126, as illustrated.

By means of the pedestaled wafer carrier shown in FIG. 4, a wafer that is larger in diameter than the susceptor recess is readily accommodated in the reactor.

FIG. 5 is a sectional elevation view of a multi-recess wafer carrier 136 according to another embodiment of the invention, reposed in a recess of a susceptor 134 mounted in a reactor 130.

The reactor 130 includes the reactor housing 132 defining an interior volume in which the susceptor 134 is mounted. The susceptor 134 has a recess therein in which is positioned the wafer carrier 136.

The wafer carrier 136 is formed as shown, containing a multiplicity of recesses 138, 140 and 142, in which are mounted the wafers 146, 148 and 150, respectively. The recesses 138, 140 and 142 in the FIG. 5 embodiment each have a concave character, whereby the wafer in such recess is supported therein at its edge or peripheral region.

It will be appreciated that the recesses in the susceptor and wafer carrier, in the broad practice of the present invention, may be of any suitable size and shape/conformation, as efficicacious in the specific use or application envisioned.

The features and advantages of the invention are more fully shown with reference to the following non-limiting example.

### EXAMPLE

A wafer carrier was constructed of the general type shown in FIGS. 1 and 2 hereof. The wafer carrier was constructed of silicon carbide with a recess of 100 mm diameter therein. The overall wafer carrier diameter was 150 mm. The edges of the wafer were thinned to allow the wafer to readily fit into the slots of a wafer carrier cassette.

Mechanical tests were conducted and the wafer carrier and 100 mm wafer were successfully transferred into and subsequently removed from the growth chamber of the epitaxial reactor (Centura reactor, commercially available from Applied Materials, Inc.).

A comparative test was then conducted of epitaxial thin film growth on wafers of 100 mm diameter and 150 mm diameter, in which the 150 mm diameter wafer was directly inserted into a correspondingly sized and shaped recess in the susceptor of the reactor, and in which the 100 mm diameter wafer was processed in a 150 mm diameter wafer carrier which in turn was inserted into the recess in the susceptor of the reactor.

The test structure was a silicon germanium (SiGe) HBT transistor structure including a SiGe layer with a specific graded profile and boron doping with a specific dopant profile.

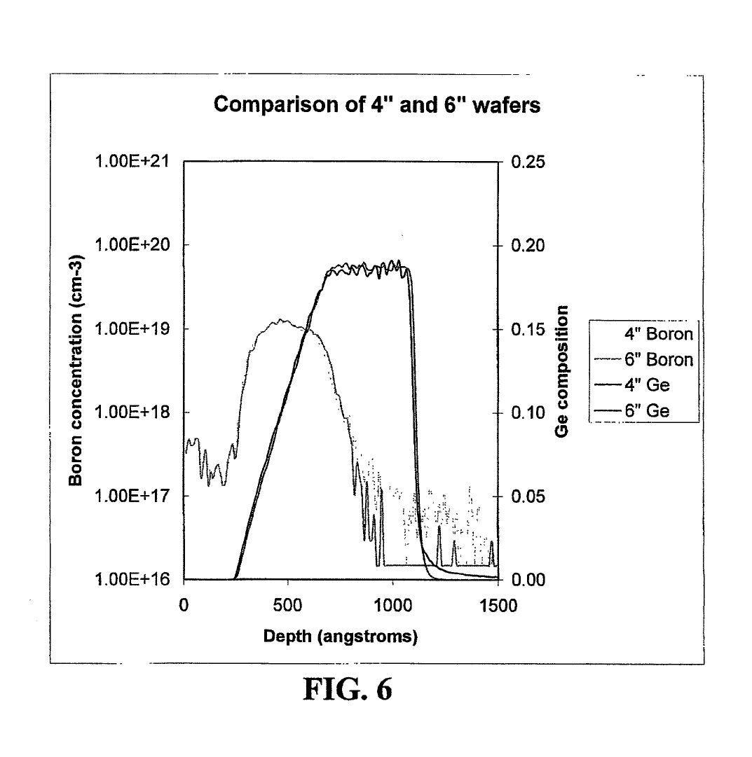

FIG. 6 is a graph of boron concentration and germanium concentration, as a function of depth in the wafer, in Angstroms, for the two wafers, viz., a 100 mm diameter wafer grown using a wafer carrier in accordance with the present invention, and a corresponding 150 mm diameter wafer grown directly in the reactor. The concentration/depth profiles were determined by SIMS (Secondary Ion Mass Spectrometry).

FIG. 6 shows that there is no significant difference in layer thicknesses and doping and composition values for the respective wafers. Additionally, the profiles of boron and germanium are virtually identical in each wafer (no scaling was performed to force any matching or registration of the profiles).

These results evidence the utility of the wafer carrier of the present invention as providing a structure accommodating smaller diameter wafers without the necessity of full system reconfiguration and/or process modification to achieve the same process results.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art. The invention therefore is to be broadly construed, consistent with the claims hereafter set forth.

What is claimed is:

1. A wafer carrier enabling a wafer of different size and/or shape to be processed in a process tool configured for processing a wafer of a predetermined size and/or shape, wherein the wafer carrier has said predetermined size and/or shape and includes at least one recess therein having said different size and/or shape.

2. The wafer carrier of claim 1, wherein said different size and/or shape differs from said predetermined size and/or shape, in respective shapes.

3. The wafer carrier of claim 1, wherein said different size and/or shape differs from said predetermined size and/or shape, in respective sizes.

4. The wafer carrier of claim 1, having a wafer in a recess therein, in close-fit relationship to the recess.

5. The wafer carrier of claim 4, wherein each of the wafer carrier and said recess therein has a cylindrical shape.

6. The wafer carrier of claim 5, wherein said wafer carrier has an outer diameter on the order of 150 mm, and the wafer and wafer recess have a diameter on the order of 100 mm.

7. The wafer carrier of claim 5, wherein said wafer carrier has an outer diameter on the order of 200 mm, and the wafer and the wafer recess have a diameter on the order of 100 mm.

8. The wafer carrier of claim 5, wherein said wafer carrier has an outer diameter on the order of 200 mm, and the wafer and the wafer recess have a diameter on the order of 150 mm.

9. The wafer carrier of claim 5, wherein said wafer carrier has an outer diameter on the order of 150 mm, and the wafer and the wafer recess have a diameter on the order of 125 mm.

10. The wafer carrier of claim 1, having a generally planar body.

11. The wafer carrier of claim 1, having a circular shape.

12. The wafer carrier of claim 1, wherein the recess has a flat floor, whereby a correspondingly flat wafer can be reposed in the recess with a main bottom face of the wafer in contact over its facial area with the floor of the recess.

13. The wafer carrier of claim 1, having a flat bottom face that is reposable in direct contact with a recess in a susceptor over the bottom facial area of the wafer carrier.

14. The wafer carrier of claim 1, formed of a semiconductor wafer material of construction.

15. The wafer carrier of claim 1, formed of a material selected from the group consisting of silicon carbide, silicon, quartz, graphite, boron nitride, aluminum oxide, aluminum nitride, silicon carbide on graphite, titanium carbide on graphite, glassy carbon, sapphire, indium phosphide, gallium antimonide, gallium arsenide and III-V nitrides.

16. The wafer carrier of claim 1, wherein the wafer carrier is formed of a same material of construction as said wafer.

17. The wafer carrier of claim 16, wherein said material of construction comprises a material selected from the group consisting of silicon carbide, silicon, quartz, graphite, boron nitride, aluminum oxide, aluminum nitride, titanium carbide, glassy carbon, sapphire, indium phosphide, gallium antimonide, gallium arsenide and III-V nitrides.

18. The wafer carrier of claim 1, wherein the wafer carrier is formed of a different material of construction from that of said wafer.

19. The wafer carrier of claim 18, wherein the wafer carrier is formed of a material of construction that is etch-resistant in relation to an etch-susceptible material of construction of the wafer, with respect to a same etchant.

20. A process tool system, comprising:
a process tool comprising a susceptor or wafer holder having at least one recess therein of a first size and/or shape;
at least one wafer carrier of a size and shape to closely fit in a recess of said susceptor or wafer holder, said wafer carrier having a recess therein of a second size and/or shape differing from said first size and/or shape; and
at least one wafer of a size and shape to closely fit in the recess of said wafer carrier.

21. The process tool system of claim 20, wherein the process tool comprises an epitaxial reactor.

22. The process tool system of claim 21, including a susceptor having one recess.

23. The process tool system of claim 21, including a susceptor having more than one recess.

24. The process tool system of claim 21, further comprising an automated wafer handling device, arranged for handling of said wafer carrier and a wafer in the recess thereof, as a unitary wafer carrier/wafer article.

25. The process tool system of claim 21, wherein said first size and/or shape differ(s) from said second size and/or shape, in respective shapes.

26. The process tool system of claim 21, wherein said first size and/or shape differ(s) from said second size and/or shape, in respective sizes.

27. The process tool system of claim 21, wherein each of the wafer carrier and said recess therein has a cylindrical shape.

28. The process tool system of claim 27, wherein said wafer carrier has an outer diameter on the order of 150 mm, and the wafer and wafer recess have a diameter on the order of 100 mm.

29. The process tool system of claim 27, wherein said wafer carrier has an outer diameter on the order of 200 mm, and the wafer and wafer recess have a diameter on the order of 100 mm.

30. The process tool system of claim 27, wherein said wafer carrier has an outer diameter on the order of 200 mm, and the wafer and wafer recess have a diameter on the order of 150 mm.

31. The process tool system of claim 27, wherein said wafer carrier has an outer diameter on the order of 150 mm, and the wafer and wafer recess have a diameter on the order of 125 mm.

32. The process tool system of claim 21, wherein the wafer carrier has a generally planar body.

33. The process tool system of claim 21, wherein the wafer carrier has a circular shape.

34. The process tool system of claim 20, wherein the wafer carrier recess has a flat floor, and said wafer is correspondingly flat and reposed in the wafer carrier recess with a bottom face of the wafer in contact over its facial area with the floor of the wafer carrier recess.

35. The process tool system of claim 21, wherein the wafer carrier has a flat bottom face that is reposed in direct contact with a susceptor recess over a bottom facial area of the wafer carrier.

36. The process tool system of claim 21, wherein the wafer carrier is formed of a semiconductor wafer material of construction.

37. The process tool system of claim 20, wherein the wafer carrier is formed of a material selected from the group consisting of silicon carbide, silicon, quartz, sapphire, indium phosphide, gallium antimonide, gallium arsenide and III-V nitrides.

38. The process tool system of claim 21, wherein the wafer carrier is formed of a same material of construction as said wafer.

39. The process tool system of claim 38, wherein said material of construction comprises a material selected from the group consisting of silicon carbide, silicon, quartz, graphite, boron nitride, aluminum oxide, aluminum nitride, glassy carbon, sapphire, titanium carbide, indium phosphide, gallium antimonide, gallium arsenide and III-V nitrides.

40. The process tool system of claim 21, wherein the wafer carrier is formed of a different material of construction from that of said wafer.

41. The process tool system of claim 40, wherein the wafer carrier is formed of a material of construction that is etch-resistant in relation to an etch-susceptible material of construction of the wafer, with respect to a same etchant.

42. A wafer carrier according to claim 1, wherein said tool comprises a single wafer epitaxial reactor.

43. The process tool system of claim 21, wherein said epitaxial reactor comprises a single wafer epitaxial reactor.

44. The wafer carrier of claim 1, of a pedestaled form.

45. The wafer carrier of claim 44, comprising a single cylindrical recess of a first diameter, and a columnar base with a second diameter that is smaller than said first diameter.

46. The process tool system of claim 21, comprising a susceptor, wherein said wafer carrier recess is of a larger diameter than said susceptor recess.

47. The wafer carrier of claim 1, comprising a cylindrical recess of a first diameter, and a columnar base with a second diameter that is smaller than said first diameter.

48. The wafer carrier of claim 1, wherein said predetermined size is larger than said different size.

49. The wafer carrier of claim 1, wherein said predetermined size is smaller than said different size.

50. The wafer carrier of claim 1, having an outer edge of a same thickness as a thickness of a wafer having a same diameter as the wafer carrier.

51. The process tool system of claim 20, including a susceptor having one recess.

52. The process tool system of claim 20, including a susceptor having more than one recess.

53. The process tool system of claim 20, further comprising an automated wafer handling device, arranged for handling of said wafer carrier and a wafer in the recess thereof, as a unitary wafer carrier/wafer article.

54. The process tool system of claim 20, wherein said first size and/or shape differ(s) from said second size and/or shape, in respective shapes.

55. The process tool system of claim 20, wherein said first size and/or shape differ(s) from said second size and/or shape, in respective sizes.

56. The process tool system of claim 20, wherein each of the wafer carrier and said recess therein has a cylindrical shape.

57. The process tool system of claim 20, wherein said wafer carrier has an outer diameter on the order of 150 mm, and the wafer and wafer recess have a diameter on the order of 100 mm.

58. The process tool system of claim 20, wherein said wafer carrier has an outer diameter on the order of 200 mm, and the wafer and wafer recess have a diameter on the order of 100 mm.

59. The process tool system of claim 20, wherein said wafer carrier has an outer diameter on the order of 200 mm, and the wafer and wafer recess have a diameter on the order of 150 mm.

60. The process tool system of claim 20, wherein said wafer carrier has an outer diameter on the order of 150 mm, and the wafer and wafer recess have a diameter on the order of 125 mm.

61. The process tool system of claim 20, wherein the wafer carrier has a generally planar body.

62. The process tool system of claim 20, wherein the wafer carrier has a circular shape.

63. The process tool system of claim 20, wherein the wafer carrier has a flat bottom face that is reposed in direct contact with a susceptor recess over a bottom facial area of the wafer carrier.

64. The process tool system of claim 20, wherein the wafer carrier is formed of a semiconductor wafer material of construction.

65. The process tool system of claim 20, wherein the wafer carrier is formed of a same material of construction as said wafer.

66. The process tool system of claim 65, wherein said material of construction comprises a material selected from the group consisting of silicon carbide, silicon, quartz, graphite, boron nitride, aluminum oxide, aluminum nitride, glassy carbon, sapphire, titanium carbide, indium phosphide, gallium antimonide, gallium arsenide and III-V nitrides.

67. The process tool system of claim 20, wherein the wafer carrier is formed of a different material of construction from that of said wafer.

68. The process tool system of claim 67, wherein the wafer carrier is formed of a material of construction that is etch-resistant in relation to an etch-susceptible material of construction of the wafer, with respect to a same etchant.

69. A method of processing a wafer in a process tool including a susceptor or wafer holder having a recess therein of different size and/or shape than the wafer, said method comprising:
providing a wafer carrier having (i) a size and shape to closely fit in the recess of the susceptor or wafer holder, and (ii) a recess therein with a size and shape accommodating close-fit positioning of the wafer therein;
positioning the wafer in the wafer carrier recess to form a wafer carrier/wafer article;
positioning the wafer carrier/wafer article in the susceptor or wafer holder recess in the process tool; and
processing the wafer in the process tool to carry out at least one semiconductor manufacturing operation thereon.

70. The method of claim 69, wherein said semiconductor manufacturing operation comprises deposition of an epitaxial film material.
